(19) United States
(12) Patent Application Publication
(10) Pub. No.: US 2025/0126985 A1
(43) Pub. Date: Apr. 17, 2025

(54) DISPLAY DEVICE AND METHOD FOR MANUFACTURING THE SAME

(71) Applicant: Samsung Display Co., LTD., Yongin-si (KR)

(72) Inventors: Chul Won PARK, Yongin-si (KR); Dong Wuuk SEO, Yongin-si (KR); Jun Hyung LIM, Yongin-si (KR); Hyun Jun JEONG, Yongin-si (KR); Seong Jun CHO, Yongin-si (KR)

(73) Assignee: Samsung Display Co., LTD., Yongin-si (KR)

(21) Appl. No.: 18/678,172

(22) Filed: May 30, 2024

(30) Foreign Application Priority Data
Oct. 16, 2023 (KR) 10-2023-0137774

(51) Int. Cl. H10K 59/124; H10K 59/12; H10K 59/121

(52) U.S. Cl. CPC H10K 59/124; H10K 59/1201; H10K 59/1213

(57) ABSTRACT

A display device includes a bottom electrode on a substrate, and including a first electrode portion and second electrode portions on sides of the first electrode portion, a first insulating layer on the substrate and the bottom electrode, an active layer on the first insulating layer, and including a channel region on the first electrode portion and a source and a drain region on the second electrode portions, a gate insulating layer on the channel region, and exposing the source and the drain region, and a gate electrode on the gate insulating layer, and overlapping the channel region. The first insulating layer and the active layer includes a valley in a corresponding area between the first electrode portion and the second electrode portions. The gate insulating layer includes an end positioned on the valley of the active layer and has a length greater than the gate electrode.

### CROSS-REFERENCE TO RELATED APPLICATION(S)

This application claims priority to and benefits of Korean Patent Application No. 10-2023-0137774 under 35 U.S.C. 119, filed on Oct. 16, 2023, in the Korean Intellectual Property Office (KIPO), the entire contents of which are incorporated herein by reference.

### BACKGROUND

### 1. Technical Field

The disclosure relates to a display device and a method for manufacturing the same.

### 2. Description of the Related Art

The importance of display devices has steadily increased with the development of multimedia technology. In response to this, various display devices, including a light emitting display device, are being developed.

### SUMMARY

Aspects of the disclosure provide a display device capable of appropriately securing an effective channel length of a transistor and a method for manufacturing the same.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment of the disclosure, a display device may include a bottom electrode disposed on a substrate, and including a first electrode portion and second electrode portions positioned on sides of the first electrode portion, a first insulating layer disposed on the substrate, and covering the bottom electrode, an active layer disposed on the first insulating layer, and including a channel region disposed on the first electrode portion of the bottom electrode and a source region and a drain region disposed on the second electrode portions of the bottom electrode, a gate insulating layer disposed on a portion of the active layer including the channel region, and exposing the source region and the drain region, and a gate electrode disposed on the gate insulating layer, and overlapping the channel region of the active layer in a thickness direction of the substrate. The first insulating layer and the active layer may include a valley in a corresponding area between the first electrode portion and the second electrode portions of the bottom electrode. The gate insulating layer may include an end positioned on the valley of the active layer and may have a length greater than a length of the gate electrode in a longitudinal direction of the channel region.

In an embodiment, the gate insulating layer may protrude over sides of the gate electrode in the longitudinal direction of the channel region and may cover a part of each of the source region and the drain region adjacent to the channel region.

In an embodiment, the substrate may include a groove overlapping the channel region and the gate electrode in the thickness direction.

In an embodiment, the first electrode portion of the bottom electrode may be disposed on the groove of the substrate.

In an embodiment, the second electrode portions of the bottom electrode may extend from the first electrode portion and disposed on a peripheral portion of the groove of the substrate and may have a height greater than a height of the first electrode portion.

In an embodiment, the bottom electrode may include a valley positioned at a boundary between the first electrode portion and the second electrode portions and corresponding to the groove of the substrate.

In an embodiment, the first electrode portion and the second electrode portions of the bottom electrode may be spaced apart from each other in an area in which the channel region and the source and drain regions are connected.

In an embodiment, the bottom electrode may include an opening positioned between the first electrode portion and the second electrode portions.

In an embodiment, the display device may further include a second insulating layer disposed on the first insulating layer and covering the active layer, the gate insulating layer, and the gate electrode.

In an embodiment, the first transistor may include at least one of, a source electrode disposed on the second insulating layer, and connected to the source region of the active layer, and a drain electrode disposed on the second insulating layer and connected to the drain region of the active layer.

In an embodiment, the display device may further include a third insulating layer disposed on the second insulating layer and covering at least one of the source electrode and the drain electrode, a light emitting element layer including a light emitting element disposed on the third insulating layer, and an encapsulation layer covering the light emitting element layer.

According to an embodiment of the disclosure, a method for manufacturing a display device, may include forming, on a substrate, a bottom electrode including a first electrode portion and second electrode portions positioned on sides of the first electrode portion, forming, on the substrate, a first insulating layer covering the bottom electrode and including a valley in a corresponding area between the first electrode portion and the second electrode portions of the bottom electrode, forming, on the first insulating layer, an active layer on the first electrode portion and the second electrode portions of the bottom electrode, sequentially forming a gate insulating layer covering the active layer and a conductive layer covering the gate insulating layer, on the first insulating layer, disposing a mask overlapping the first electrode portion of the bottom electrode in a thickness direction of the substrate, on the conductive layer, forming a gate electrode under the mask by etching the conductive layer, extending a width of the mask such that the mask covers a side surface of the gate electrode, and etching the gate insulating layer to cover a portion of the active layer that overlaps the mask and expose another portion of the active layer.

In an embodiment, the extending of the width of the mask may include reflowing the mask through a heat treatment process.

In an embodiment, after the reflowing of the mask, an end of the mask may be positioned on the valley of the first insulating layer.

In an embodiment, after the etching of the gate insulating layer, the gate insulating layer may cover a channel region of the active layer and a portion adjacent to the channel region and may expose a remaining portion of the active layer.

In an embodiment, the method may further include, before the forming of the bottom electrode, forming a groove in the substrate by etching the substrate to correspond to an area in which the first electrode portion of the bottom electrode is to be positioned.

In an embodiment, the bottom electrode may be formed on the groove of the substrate and a peripheral portion of the groove.

In an embodiment, the bottom electrode may be formed to include an opening between the first electrode portion and the second electrode portions.

In an embodiment, the method may further include, after the etching of the gate insulating layer, forming a second insulating layer covering the active layer, the gate insulating layer, and the gate electrode on the first insulating layer.

In an embodiment, the method may further include, forming at least one of a source electrode connected to the source region of the active layer and a drain electrode connected to a drain region of the active layer, on the second insulating layer.

According to the display device and the method for manufacturing the same according to embodiments, a stepped portion or a valley may be formed below a gate insulating layer corresponding to an area to be formed by extending the gate insulating layer, and the gate insulating layer may be etched after extending a width of a mask used for etching a gate electrode. In some embodiments, a stepped portion or a valley may be formed in the gate insulating layer by forming a groove in a substrate or patterning a bottom electrode, corresponding to the area to be formed by extending the gate insulating layer. As a result, a reflow range of the mask may be appropriately limited in a reflow process or the like to extend the width of the mask.

According to embodiments, the gate insulating layer having an extended width or length as compared with the gate electrode may be formed under the gate electrode by utilizing a mask used to form the gate electrode. Accordingly, the operating characteristics of the transistor may be improved by appropriately securing an effective channel length of the transistor, and the manufacturing process of the display device may be simplified.

However, effects according to the embodiments of the disclosure are not limited to those described above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a plan view illustrating a display device according to an embodiment;

FIG. 2 is a plan view illustrating a display panel of FIG. 1;

FIG. 3 is a schematic cross-sectional view illustrating the display panel according to an embodiment;

FIG. 4 is a schematic cross-sectional view illustrating the display panel according to an embodiment;

FIG. 5 is a schematic plan view showing the bottom electrode according to an embodiment;

FIGS. 6 to 18 are schematic cross-sectional views showing a method for manufacturing the display device according to an embodiment; and

FIGS. 19 and 20 are schematic cross-sectional views illustrating a method for manufacturing the display device according to an embodiment.

### DETAILED DESCRIPTION OF THE EMBODIMENTS

The embodiments will now be described more fully hereinafter with reference to the accompanying drawings, in which embodiments of the disclosure are shown. The disclosure may, however, be embodied in different forms and should not be construed as limited to the embodiments set forth herein. Rather, these embodiments are provided so that this disclosure will be more thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Features of each of various embodiments of the disclosure may be partially or entirely combined with each other and may technically variously interwork with each other, and respective embodiments may be implemented independently of each other or may be implemented together in association with each other.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

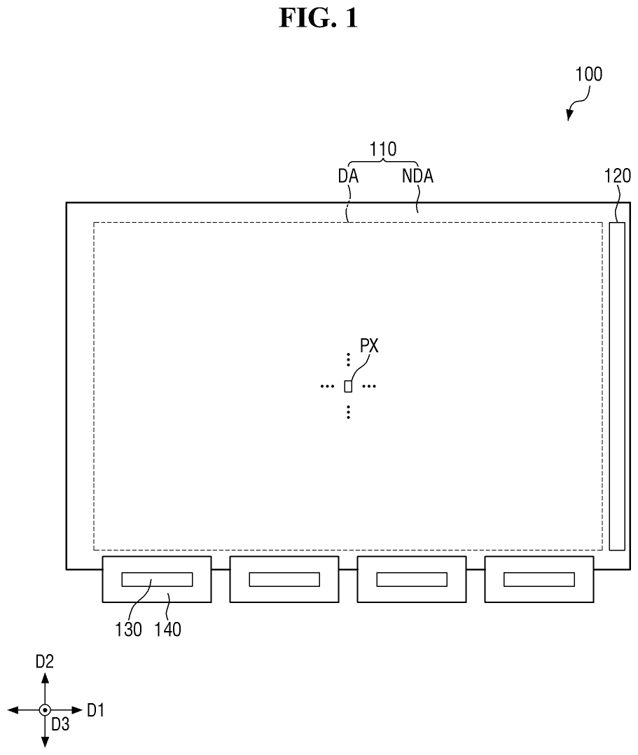

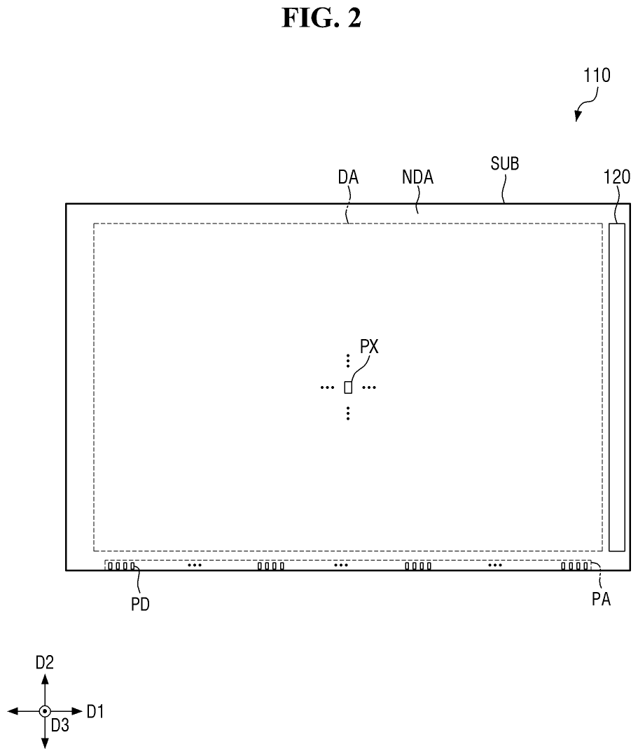

FIG. 1 is a plan view illustrating a display device 100 according to an embodiment. FIG. 2 is a plan view illustrating a display panel 110 of FIG. 1.

Referring to FIGS. 1 and 2, the display device 100 may be a device for displaying a moving image or a still image. The display device 100 may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC). However, the disclosure is not limited thereto, and the display device 100 may be applicable to various other types of electronic devices.

In one embodiment, the display device 100 may be a light emitting display device such as an organic light emitting display including an organic light emitting diode, a quantum dot light emitting display including a quantum dot light emitting layer, an inorganic light emitting display including an inorganic semiconductor, or an ultra-small light emitting display using an ultra-small light emitting diode such as a micro or nano light emitting diode (micro LED or nano LED), but the disclosure is not limited thereto. For example, the display device 100 may be another type of display device other than a light emitting display device. In the following, embodiments in which the display device 100 is an organic light emitting display device will be disclosed.

The display device 100 may include a display panel 110 including pixels PX, and a first driver 120 and a second driver 130 configured to supply driving signals to the pixels PX. The display device 100 may further include additional components. For example, the display device 100 may include a power supply unit for supplying power voltages to the pixels PX, the first driver 120, the second driver 130, and a timing controller for controlling the operations of the first driver 120 and the second driver 130.

The display panel 110 may include a display area DA and a non-display area NDA. The display area DA may be an area including the pixels PX to display an image. For example, the display area DA may include pixel areas in which each of the pixels PX is disposed. The non-display area NDA is an area other than the display area DA, and an image may not be displayed in the non-display area NDA. In one embodiment, the non-display area NDA may be positioned adjacent to the display area DA. For example, the non-display area NDA may surround the display area DA in a plan view.

In FIGS. 1 and 2, a first direction D1, a second direction D2, and a third direction D3 are defined. In one embodiment, the first direction D1 may be the horizontal direction of the display panel 110, and the second direction D2 may be the vertical direction of the display panel 110. The third direction D3 may be a thickness direction of the display panel 110.

In one embodiment, the display panel 110 may have a rectangular shape in plan view. Although FIGS. 1 and 2 illustrate the display panel 110 with a horizontal length longer than a vertical length, the shape of the display panel 110 is not limited thereto. For example, the display panel 110 may have a shape in which the vertical length is longer than the horizontal length, or may have a square shape, or the like. The display panel 110 may include angled corners or include rounded corners.

The planar shape of the display panel 110 is not limited to the illustrated quadrilateral shape, and the display panel 110 may have other shapes. For example, the display panel 110 may have a non-quadrilateral polygonal shape, a circular shape, an elliptical shape, an atypical shape, or another shape in plan view.

In one embodiment, the display panel 110 may be substantially flat on the plane defined by the first direction D1 and the second direction D2, and may have a uniform thickness in the third direction D3. In another embodiment, the display panel 110 may be provided in a three-dimensional shape having a curved surface or the like.

The display panel 110 may be provided as a rigid panel so as not to be substantially transformed, or as a flexible panel that can be transformed to be at least partially folded, bent, or rolled. The display panel 110 may be provided to the display device 100 without bending, or may be provided to the display device 100 while being partially bent.

The display panel 110 may include a substrate SUB and pixels PX disposed on the substrate SUB. The pixels PX may be disposed in the display area DA on the substrate SUB.

The substrate SUB, which is a base member for manufacturing or providing the display panel 110, may form the base surface of the display panel 110. The substrate SUB may include the display area DA and the non-display area NDA adjacent to the display area DA.

The display area DA may have various shapes depending on embodiments. For example, the display area DA may have a quadrilateral shape, a non-quadrilateral polygonal shape, a circular shape, an elliptical shape, an atypical shape, or another shape. In one embodiment, the display area DA may have a shape corresponding to the shape of the display panel 110, but the disclosure is not limited thereto.

The pixels PX may be provided and/or arranged in the display area DA. For example, the display area DA may include multiple pixel areas in which each of the pixels PX is disposed.

In one embodiment, the display device 100 may be a light emitting display device, and each pixel PX may include a light emitting element positioned in each emission area and a pixel circuit connected to the light emitting element. In describing embodiments, the term “connect” may include electrical connection and/or physical connection. Each pixel circuit may include transistors (e.g., pixel transistors including a driving transistor that generates a driving current corresponding to a data signal, and at least one switching transistor) and at least one capacitor (e.g., a pixel capacitor including a storage capacitor).

The non-display area NDA may include a pad area PA in which pads PD are disposed, and may optionally further include a driving circuit area. The driving circuit area may be positioned on at least one side of the display area DA. At least one driver, pads PD, and/or wires may be disposed in the non-display area NDA.

At least one driver for driving the pixels PX, or a part of the driver may be disposed in the driving circuit area. For example, circuit elements constituting the first driver 120 (e.g., driver transistors and driver capacitors constituting stage circuits of the first driver 120) may be disposed in the driving circuit area on the substrate SUB. In one embodiment, the circuit elements of the first driver 120 may be formed in the display panel 110 together with the pixels PX.

The pads PD may be disposed in the pad area PA. At least one circuit board 140 may be disposed and/or bonded on the pad area PA. In one embodiment, multiple circuit boards 140 connected to different pads PD may be disposed in the pad area PA. The pads PD may include signal pads and power pads for transmitting driving signals and power voltages required for driving the pixels PX and/or the first driver 120 into the display panel 110.

The first driver 120 and the second driver 130 may generate driving signals for controlling operation timing, luminance, and the like of the pixels PX, and may supply the generated driving signals to the pixels PX. For example, the first driver 120 may be a gate driver including a scan driver, and may be connected to the pixels PX through respective gate lines. The first driver 120 may supply respective gate signals (e.g., control signals that control the driving timing of the pixels PX, including scan signals and/or emission control signals) to the pixels PX. The second driver 130 may be a data driver including source driving circuits, and may be connected to the pixels PX through respective data lines. The second driver 130 may supply respective data signals to the pixels PX.

In one embodiment, at least one of the first driver 120 or the second driver 130, or a part of the at least one of the first driver 120 or the second driver 130 may be embedded in the display panel 110. For example, the first driver 120 or a part of the first driver 120 may be disposed and/or formed in the non-display area NDA and disposed on the substrate SUB of the display panel 110.

Although FIG. 1 illustrates that the first driver 120 is formed on a side of the display area DA (for example, in the non-display area NDA on the right side of the display area DA), the disclosure is not limited thereto. For example, the first driver 120 may be positioned only on another side (e.g., the non-display area NDA on the left side of the display area DA) of the display area DA, or may be positioned on both sides (e.g., the non-display area NDA on the left side and right side of the display area DA) of the display area DA. In another embodiment, a portion of the first driver 120 may be positioned in the non-display area NDA, and another portion of the first driver 120 may be positioned in a non-emission area (e.g., the area between the emission areas of the pixels PX) inside the display area DA.

In one embodiment, another one or a part of another one of the first driver 120 and the second driver 130 may be disposed or formed outside the display panel 110 to be electrically connected to the display panel 110. For example, the second driver 130 may be implemented with multiple integrated circuit chips and may be disposed on the circuit boards 140 electrically connected to the pixels PX of the display panel 110. The second driver 130 may be implemented as at least one integrated circuit chip and mounted on the non-display area NDA of the display panel 110.

The circuit board 140 may be connected to the display panel 110 through the pads PD. In one embodiment, the circuit board 140 may be a flexible film such as a flexible printed circuit board (FPCB), a printed circuit board (PCB), or a chip on film (COF), but the disclosure is not limited thereto. In one embodiment, the circuit board 140 may be connected to the timing controller and/or the power supply unit through another circuit board, connector, or the like.

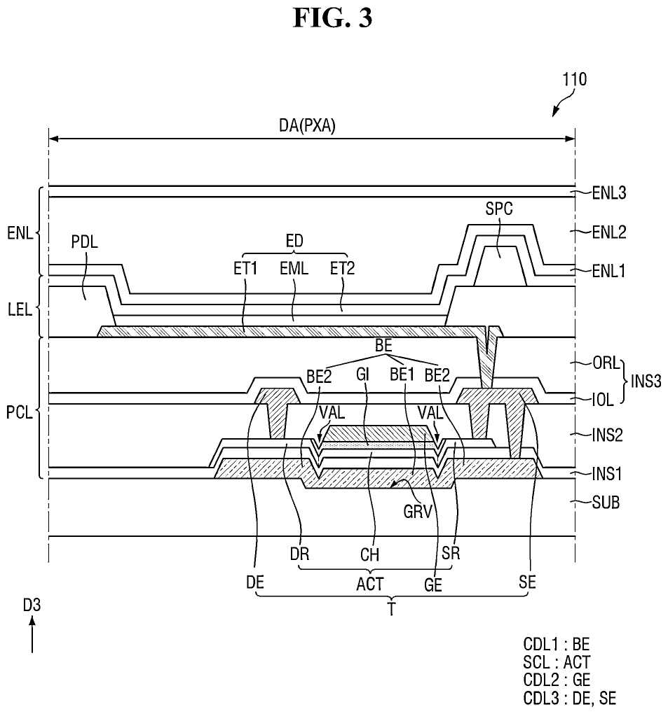

FIG. 3 is a schematic cross-sectional view illustrating the display panel 110 according to an embodiment. For example, FIG. 3 schematically illustrates a part of the display area DA of the display panel 110. FIG. 3 schematically illustrates a light emitting display panel including a light emitting element ED (for example, an organic light emitting diode) as an embodiment of the display panel 110. However, the type and/or structure of the display panel 110 are not limited thereto.

Referring to FIG. 3 in addition to FIGS. 1 and 2, the display panel 110 may include the substrate SUB (also referred to as “base layer”), a panel circuit layer PCL, a light emitting element layer LEL, and an encapsulation layer ENL. The panel circuit layer PCL, the light emitting element layer LEL, and the encapsulation layer ENL may be disposed on the substrate SUB and overlap with each other in the third direction D3. For example, with respect to the display area DA, the panel circuit layer PCL, the light emitting element layer LEL, and the encapsulation layer ENL may be sequentially arranged or formed on the substrate SUB along the third direction D3. However, the disclosure is not limited thereto, and the positions of the panel circuit layer PCL, the light emitting element layer LEL, and/or the encapsulation layer ENL may be changed.

In one embodiment, the display panel 110 may further include additional elements provided above and/or under the encapsulation layer ENL. For example, the display panel 110 may further include at least one of a sensor layer (for example, a touch sensor layer), an optical layer (for example, a color filter layer and/or a wavelength conversion layer), and a passivation layer (for example, a passivation film, an insulating layer, an upper substrate, and/or a window). Each of the sensor layer, the optical layer, and/or the passivation layer may be provided above the encapsulation layer ENL or may be provided between the light emitting element layer LEL and the encapsulation layer ENL.

The substrate SUB may a base member for forming the display panel 110 and may be a rigid or flexible substrate (or film). In one embodiment, the substrate SUB may be a substrate including an insulating material such as glass or the like and having rigid characteristics, and may not be bent. In another embodiment, the substrate SUB may be a flexible substrate that includes polyimide or another insulating material and may be transformed to be bent, folded, or rolled, and may or may not be bent. The type and/or material of the substrate SUB may change depending on embodiments.

In one embodiment, the substrate SUB may include a groove GRV positioned in an area in which at least one transistor T is disposed. The groove GRV may overlap a gate electrode GE and a portion including a channel region CH of an active layer ACT included in the at least one transistor T in the third direction D3. The groove GRV may also overlap a first electrode portion BE1 of a bottom electrode BE positioned below the channel region CH of the active layer ACT in the third direction D3.

In one embodiment, the display panel 110 may further include a barrier layer (e.g., an inorganic insulating layer capable of blocking moisture permeation) disposed between the substrate SUB and the panel circuit layer PCL. For example, the barrier layer and the panel circuit layer PCL may be sequentially disposed on the substrate SUB, or the panel circuit layer PCL may be disposed on (e.g., directly disposed on) the substrate SUB.

The panel circuit layer PCL may include the pixels PX and/or circuit elements of the first driver 120 (e.g., pixel transistors and pixel capacitors provided to the pixels PX, and/or driver transistors and/or driver capacitors provided to the first driver 120), and wires (e.g., signal lines and power lines). In one embodiment, the panel circuit layer PCL may include additional conductive patterns (e.g., bridge patterns).

FIG. 3 schematically illustrates one transistor T (e.g., the transistor T connected to the light emitting element ED of the corresponding pixel PX) disposed in one pixel area PXA, as an embodiment of circuit elements that may be provided or disposed on the panel circuit layer PCL. The transistor T in FIG. 3 may be a driving transistor or a switching transistor provided in the pixel circuit of the corresponding pixel PX.

The panel circuit layer PCL may further include multiple insulating layers and/or insulating patterns disposed on the substrate SUB. For example, the panel circuit layer PCL may include a first insulating layer INS1, a gate insulating layer GI, a second insulating layer INS2, and a third insulating layer INS3 that are sequentially disposed on the substrate SUB along the third direction D3.

In one embodiment, at least one insulating layer provided on the panel circuit layer PCL may be disposed in an entire area of the display area DA. For example, the first insulating layer INS1, the second insulating layer INS2, and the third insulating layer INS3 may be disposed in an entire area of the display area DA.

In one embodiment, the gate insulating layer GI may be disposed on only a portion of the active layer ACT provided in the transistor T, and may not be disposed on another portion of the active layer ACT. For example, the gate insulating layer GI may be individually disposed corresponding to the area in which each of the transistors T is formed, and may be an insulating pattern that covers a portion of the active layer ACT provided to the corresponding transistor T and exposes another portion of the active layer ACT.

The transistor T may include the active layer ACT (also referred to as an “active pattern” or “semiconductor pattern”) and the gate electrode GE that overlaps a part of the active layer ACT in the third direction D3. In embodiments, the transistor T may be a transistor of a top-gate structure. For example, the gate electrode GE of the transistor T may be disposed on the gate insulating layer GI covering the active layer ACT.

In one embodiment, the transistor T may further include at least one of a source electrode SE and a drain electrode DE. For example, the transistor T may further include a source electrode SE connected to a source region SR of the active layer ACT and a drain electrode DE connected to a drain region DR of the active layer ACT. In another embodiment, the transistor T may not include a separate source electrode and/or drain electrode, and the source region SR and/or drain region DR of the active layer ACT may be connected to other circuit elements, wires, and/or conductive patterns, or the like to function as the source electrode and/or drain electrode of the transistor T.

In embodiments, the bottom electrode BE (also referred to as a “bottom gate electrode” or “lower electrode”) may be disposed under the active layer ACT of the transistor T. In one embodiment, the bottom electrode BE may be connected to an electrode of the transistor T and may be utilized as a back-gate electrode to adjust the characteristics of the transistor T, and the bottom electrode BE may be an element included in the transistor T. By disposing the bottom electrode BE below the active layer ACT, it may be possible to block external light from entering the active layer ACT (e.g., the channel region CH) and stabilize the operating characteristics of the transistor T.

In one embodiment, the bottom electrode BE may be connected to the source electrode SE or the gate electrode GE of the transistor T. For example, the transistor T may be a driving transistor of the pixel PX, and the bottom electrode BE may be connected to the source electrode SE of the transistor T. In another embodiment, the transistor T may be a switching transistor of the pixel PX, and the bottom electrode BE may be connected to the gate electrode GE of the transistor T.

In one embodiment, the transistor T may be an N-type transistor. For example, the transistor T may be an N-type oxide transistor.

The bottom electrode BE may be provided in the first conductive layer CDL1 on the substrate SUB. In one embodiment, the first conductive layer CDL1 may be disposed between the substrate SUB and the first insulating layer INS1. For example, the first conductive layer CDL1 may be disposed on the substrate SUB, and may be covered by the first insulating layer INS1.

The bottom electrode BE may include a first electrode portion BE1 and second electrode portions BE2 positioned on both sides of the first electrode portion BE1. The bottom electrode BE may overlap the active layer ACT in the third direction D3. For example, the first electrode portion BE1 of the bottom electrode BE may overlap the channel region CH of the active layer ACT, and the second electrode portions BE2 of the bottom electrode BE may overlap the source region SR and the drain region DR of the active layer ACT in the third direction D3.

In one embodiment, the first electrode portion BE1 of the bottom electrode BE may be disposed on the groove GRV of the substrate SUB. The second electrode portions BE2 of the bottom electrode BE may extend from the first electrode portion BE1 and be disposed on the peripheral portion of the groove GRV of the substrate SUB.

The bottom electrode BE may have a stepped portion corresponding to the groove GRV of the substrate SUB. For example, the second electrode portions BE2 of the bottom electrode BE may be positioned at a height higher than a height of the first electrode portion BE1. In one embodiment, the bottom electrode BE may entirely have a uniform thickness except for an inclined surface or the like, and the height difference between the first electrode portion BE1 and the second electrode portions BE2 of the bottom electrode BE may correspond to the depth of the groove GRV.

In one embodiment, the bottom electrode BE may include a valley VAL positioned at the boundary between the first electrode portion BE1 and the second electrode portions BE2 and correspond to the groove GRV of the substrate SUB. For example, the bottom electrode BE may have a thickness greater than or equal to the depth of the groove GRV formed in the substrate SUB, and may have the valley VAL formed around the perimeter of the groove GRV.

The first insulating layer INS1 may be disposed on the bottom electrode BE. In one embodiment, the first insulating layer INS may have the valley VAL corresponding to the valley VAL of the bottom electrode BE. For example, the first insulating layer INS1 may include the valley VAL in a corresponding area between the first electrode portion BE1 and the second electrode portions BE2 of the bottom electrode BE and/or the boundary thereof.

The active layer ACT may be disposed on the first insulating layer INS1. The active layer ACT may be provided in a semiconductor layer SCL on the substrate SUB. In one embodiment, the semiconductor layer SCL may be disposed on the first insulating layer INS1 covering the first conductive layer CDL1 and may be covered by the gate insulating layer GI and the second insulating layer INS2.

The active layer ACT may include a channel region CH, and a source region SR and a drain region DR spaced apart from each other with the channel region CH interposed between the source region SR and the drain region DR. For example, the source region SR and the drain region DR may each be positioned on a side of the channel region CH. The channel region CH may be a region that maintains semiconductor characteristics without becoming conductive. The source region SR and the drain region DR, which are regions that have become conductive, may have a carrier concentration (for example, electron concentration) higher than a carrier concentration of the channel region CH.

The active layer ACT may overlap the bottom electrode BE and the gate electrode GE in the third direction D3. For example, a part of the active layer ACT including the channel region CH may overlap the bottom electrode BE and the gate electrode GE in the third direction D3

In one embodiment, the channel region CH of the active layer ACT may be disposed on the first electrode portion BE1 of the bottom electrode BE, and the source region SR and drain region DR of the active layer ACT may be disposed on the second electrode portions BE2 of the bottom electrode BE. In one embodiment, the active layer ACT may have the valley VAL corresponding to the valley VAL of the bottom electrode BE and the first insulating layer INS1. For example, the active layer ACT may include the valley VAL in a corresponding area between the first electrode portion BE1 and the second electrode portions BE2 of the bottom electrode BE and/or the boundary thereof.

In one embodiment, the active layer ACT may include an oxide semiconductor including at least one of indium (In), gallium (Ga), zinc (Zn), tin (Sn), or hafnium (Hf), and another oxide semiconductor. For example, the active layer ACT may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), indium-tin-gallium-zinc oxide (ITGZO), and the like.

In one embodiment, the active layer ACT may be formed of a high-mobility oxide semiconductor (for example, an oxide semiconductor material with mobility of greater than or equal to approximately 20 cm²/Vs or approximately 30 cm²/Vs). For example, the active layer ACT may include indium-gallium-zinc oxide (IGZO) or indium-tin-gallium-zinc oxide (ITGZO), and may have a mobility of greater than or equal to approximately 30 cm²/Vs. In case that the active layer ACT is formed of a high-mobility oxide semiconductor, the conductivity of the source region SR and the drain region DR may be appropriately and/or readily secured without performing an additional doping process. In case that the active layer ACT is formed of a high-mobility oxide semiconductor, the mobility or the like of the transistor T may be appropriately secured while forming the transistor T having a fine size (e.g., a size including an active layer having a width and/or length in the range of approximately several micrometers to tens of micrometers).

The gate insulating layer GI (also referred to as “gate insulating pattern”) may be disposed on the active layer ACT. The gate insulating layer GI may be disposed between the active layer ACT and the gate electrode GE.

In one embodiment, the gate insulating layer GI may be disposed on only a portion of the active layer ACT and may not disposed on another portion of the active layer ACT. For example, the gate insulating layer GI may be disposed on a portion of the active layer ACT including the channel region CH, and may expose the source region SR and the drain region DR of the active layer ACT.

As the gate insulating layer GI exposes the source region SR and the drain region DR, the source region SR and the drain region DR may be appropriately and/or readily conductive during the manufacturing process of the display panel 110. For example, in the step of etching the gate insulating layer GI such that at least a portion of each of the source region SR and the drain region DR is exposed, oxygen vacancies may form in the source region SR and the drain region DR by an etching gas or the like. Accordingly, the source region SR and the drain region DR may be appropriately conductive in a subsequent process (e.g., a process of forming the second insulating layer INS2) without performing a separate doping process.

In one embodiment, in order to limit the carrier concentration of the source region SR and the drain region DR and/or the mobility of the active layer ACT to an appropriate range, an oxygen supply layer may be formed between the gate insulating layer GI and the gate electrode GE. For example, the transistor T may be disposed between the gate insulating layer GI and the gate electrode GE and may further include an oxygen supply layer including an oxide semiconductor. The active layer ACT and the oxygen supply layer of the transistor T may include a same oxide semiconductor or include different oxide semiconductors.

In embodiments, the gate insulating layer GI may have a length greater than a length of the gate electrode GE above the gate insulating layer GI in the longitudinal direction of the channel region CH of the active layer ACT (e.g., in the direction leading from an end of the channel region CH adjacent to the source region SR to another end of the channel region CH adjacent to the drain region DR). For example, the gate insulating layer GI may protrude over both sides of the gate electrode GE in the longitudinal direction of the channel region CH. Accordingly, the gate insulating layer GI may cover a portion of the active layer ACT that overlaps the gate electrode GE in the third direction D3, and may further cover another portion of the active layer ACT that is adjacent to the portion of the active layer ACT and does not overlap the gate electrode GE in the third direction D3. For example, the gate insulating layer GI may cover at least a portion of the active layer ACT including the channel region CH, and may further cover another portion of the active layer ACT including a portion of each of the source region SR and drain region DR adjacent to the channel region CH. The gate insulating layer GI may not be disposed on the remaining portion of the active layer ACT, for example, the remaining portion of each of the source region SR and drain region DR, and accordingly, may expose the remaining portion of each of the source region SR and the drain region DR.

The gate insulating layer GI may extend over both sides of the gate electrode GE to further cover a part of each of the source region SR and drain region DR, so that the effective channel length of the transistor T may be appropriately extended and/or secured. Accordingly, the operating characteristics of the transistor T may be improved and/or secured.

In one embodiment, the end of the gate insulating layer GI may be positioned on the valley VAL of the active layer ACT. For example, the gate insulating layer GI may have a width and/or length that extends from the upper portion of the channel region CH of the active layer ACT to the upper portion of the area of the valley VAL of the active layer ACT. In one embodiment, the gate insulating layer GI may cover the valley VAL of the active layer ACT, and may have the valley VAL corresponding to the valley VAL of the bottom electrode BE, the first insulating layer INS1, and the active layer ACT. For example, the gate insulating layer GI may include the valley VAL in a corresponding area between the first electrode portion BE1 and the second electrode portions BE2 of the bottom electrode BE and/or the boundary thereof.

The gate electrode GE may be disposed on the gate insulating layer GI. The gate electrode GE may be provided in a second conductive layer CDL2 on the substrate SUB. In one embodiment, the second conductive layer CDL2 may be disposed on the gate insulating layer GI, and may be covered by the second insulating layer INS2.

The gate electrode GE may be disposed on the active layer ACT and overlap the channel region CH in the third direction D3. The gate electrode GE and the active layer ACT may be separated and/or spaced apart from each other with the gate insulating layer GI interposed between the gate electrode GE and the active layer ACT.

The second insulating layer INS2 may be disposed on the gate electrode GE. The second insulating layer INS2 may cover the active layer ACT, the gate insulating layer GI, and the gate electrode GE.

The source electrode SE and the drain electrode DE may be disposed on the second insulating layer INS2. The source electrode SE and the drain electrode DE may be provided in a third conductive layer CDL3 on the substrate SUB. In one embodiment, the third conductive layer CDL3 may be disposed on the second insulating layer INS2, and may be covered by the third insulating layer INS3.

The source electrode SE may be connected to a part of the active layer ACT. For example, the source electrode SE may be connected to the source region SR through at least one contact hole penetrating the second insulating layer INS2. In one embodiment, the source electrode SE may be further connected to the bottom electrode BE through at least one contact hole penetrating the first insulating layer INS1 and the second insulating layer INS2.

The drain electrode DE may be connected to another portion of the active layer ACT. For example, the drain electrode DE may be connected to the drain region DR through at least one contact hole penetrating the second insulating layer INS2.

In one embodiment, the display panel 110 may further include driver transistors provided in a driving circuit area in which the first driver 120 or the like of FIGS. 1 and 2 is provided. At least one driver transistor of the driver transistors may have a structure similar to the transistor T of FIG. 3. For example, the display panel 110 may include a groove formed in the substrate SUB in a transistor area corresponding to the at least one driver transistor, and may include a bottom electrode disposed on the groove and having a stepped portion and/or a valley corresponding to the groove and the driver transistor disposed on the bottom electrode. Between the active layer of the driver transistor and the gate electrode, a gate insulating layer that covers a portion including a channel region of the active layer, which has a length and/or width greater than a length and/or width of the gate electrode, and protrudes over sides of the gate electrode may be disposed.

The third insulating layer INS3 may be disposed on the circuit elements of the panel circuit layer PCL, including pixel transistors including the transistor T of FIG. 3 and/or driver transistors of the first driver 120. The third insulating layer INS3 may be disposed on the second insulating layer INS2 and may cover the circuit elements provided in the panel circuit layer PCL. For example, the third insulating layer INS3 may cover the source electrode SE and the drain electrode DE provided in the third conductive layer CDL3.

In one embodiment, the third insulating layer INS3 may have a multilayer structure including an inorganic insulating layer and an organic insulating layer. For example, the third insulating layer INS3 may include an inorganic layer IOL and an organic layer ORL sequentially disposed on the second insulating layer INS2.

The respective electrodes, conductive patterns, and/or wires provided in the conductive layers of the panel circuit layer PCL may include at least one conductive material. For example, the electrodes, the conductive patterns, and/or the wires provided in each of the first conductive layer CDL1, the second conductive layer CDL2, and the third conductive layer CDL3 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), another metal, an alloy thereof, and another conductive material. In one embodiment, the electrodes, the conductive patterns, and/or the wires disposed in a same conductive layer may be simultaneously formed using a same conductive material.

In one embodiment, each of electrodes, conductive patterns, and/or wires provided in the conductive layers of the panel circuit layer PCL may have a single-layer or multilayer structure. For example, each of the electrodes, conductive patterns, and/or wires provided in the first conductive layer CDL1, the second conductive layer CDL2, and the third conductive layer CDL3 may have a single-layer or multilayer structure.

In one embodiment, each of the first insulating layer INS1, the gate insulating layer GI, the second insulating layer INS2, and the inorganic layer IOL of the third insulating layer INS3 may include at least one inorganic insulating layer containing an inorganic insulating material (e.g., silicon nitride, silicon oxide, silicon oxynitride, titanium oxide, aluminum oxide, or another inorganic insulating material). For example, each of the first insulating layer INS1, the gate insulating layer GI, the second insulating layer INS2, and the inorganic layer IOL of the third insulating layer INS3 may be an inorganic insulating layer of a single layer or multiple layers.

In one embodiment, the organic layer ORL of the third insulating layer INS3 may include at least one organic insulating layer containing an organic insulating material (e.g., an acrylic resin, an epoxy resin, a phenolic resin, a polyamide resin, a polyimide resin, or another organic insulating material). The surface (for example, the top surface) of the organic layer ORL may be substantially flat.

The light emitting element layer LEL may be disposed on the panel circuit layer PCL. For example, the light emitting element layer LEL may be positioned at least in the display area DA and may be disposed on the third insulating layer INS3.

The light emitting element layer LEL may include a light emitting element ED for each of the pixels PX. For example, the light emitting element layer LEL may include a pixel defining layer PDL (also referred to as “bank”) that partitions the emission areas of the pixels PX and the light emitting element ED positioned in each emission area. In one embodiment, the light emitting element layer LEL may further include a spacer SPC disposed on a part of the pixel defining layer PDL.

Each of the light emitting elements ED may include a first electrode ET1 positioned in each emission area, and a light emitting layer EML and a second electrode ET2 sequentially disposed on the first electrode ET1. The first electrode ET1 of the light emitting element ED may be connected to at least one pixel transistor (e.g., the transistor T in FIG. 3) included in the corresponding pixel PX.

The first electrode ET1 of the light emitting element ED may be a single-layer or multilayer electrode including at least one conductive material. In one embodiment, the display panel 110 may be a top emission type display panel, and the first electrode ET1 may include a metal material with high reflectivity.

The light emitting layer EML of the light emitting element ED may include a high molecular material or a low molecular material. Light emitted from the light emitting layer EML may contribute to image display.

The second electrode ET2 of the light emitting element ED may include a conductive material. In one embodiment, the second electrode ET2 may be a common layer formed across the entire display area DA and cover the light emitting layer EML and the pixel defining layer PDL. In one embodiment, the display panel 110 may be a top emission type display panel, and the second electrode ET2 may include a transparent or translucent conductive material.

The pixel defining layer PDL may have an opening corresponding to each emission area and may surround the emission area in a plan view. For example, the pixel defining layer PDL may cover an edge of the first electrode ET1 of the light emitting element ED and may include an opening exposing a remaining portion of the first electrode ET1 in a plan view. A region where the exposed first electrode ET1 and the light emitting layer EML overlap in the third direction D3 may be an emission area of each pixel PX. In one embodiment, the pixel defining layer PDL may include at least one organic insulating layer containing an organic insulating material.

The spacer SPC may be disposed on a part of the pixel defining layer PDL. The spacer SPC may include at least one organic insulating layer containing an organic insulating material. The spacer SPC and the pixel defining layer PDL may include a same material or different materials. The pixel defining layer PDL and the spacer SPC may be formed sequentially through each mask process, or may be formed simultaneously and/or integrally using a halftone mask.

The encapsulation layer ENL may be disposed on the light emitting element layer LEL. The encapsulation layer ENL may cover the light emitting element layer LEL in the display area DA and may extend to the non-display area NDA to be in contact with the panel circuit layer PCL. The encapsulation layer ENL may block the permeation of oxygen or moisture into the light emitting element layer LEL, and may reduce electrical and/or physical impacts to the panel circuit layer PCL and the light emitting element layer LEL.

In one embodiment, the encapsulation layer ENL may include a first encapsulation layer ENL1, a second encapsulation layer ENL2, and a third encapsulation layer ENL3 sequentially disposed on the light emitting element layer LEL. Each of the first encapsulation layer ENL1 and the third encapsulation layer ENL3 may be an inorganic encapsulation layer containing an inorganic material. The second encapsulation layer ENL2 may be an organic encapsulation layer containing an organic material.

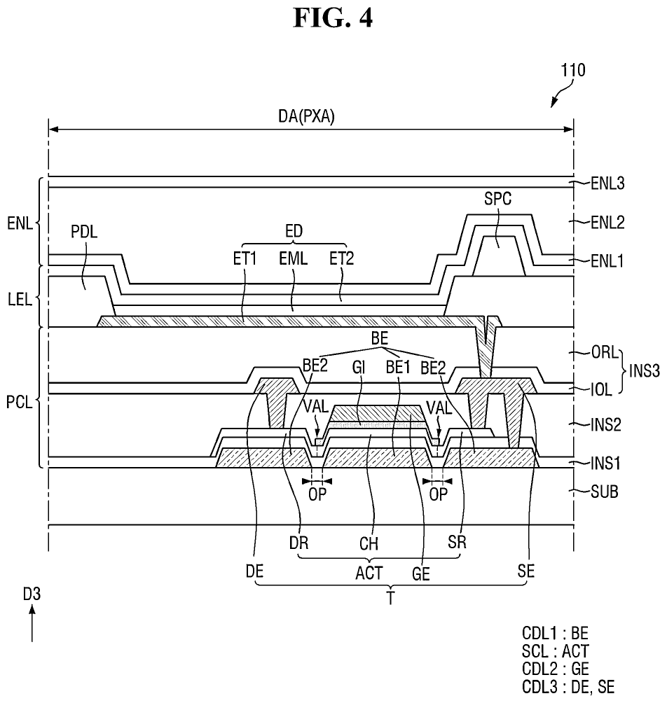

FIG. 4 is a schematic cross-sectional view illustrating the display panel 110 according to an embodiment. For example, FIG. 4 schematically illustrates a part of the display area DA of the display panel 110, and the embodiment of the display panel 110 in FIG. 4 and the embodiment of the display panel 110 in FIG. 3 may be different with respect to the bottom electrode BE or the like.

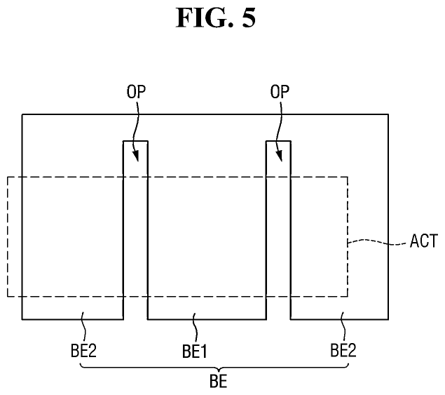

FIG. 5 is a schematic plan view showing the bottom electrode BE according to an embodiment. For example, FIG. 5 schematically shows an embodiment of the bottom electrode BE of FIG. 4. In describing the embodiments of FIGS. 4 and 5, redundant descriptions of components substantially identical or similar to those of the embodiment of FIG. 3 will be omitted.

Referring to FIGS. 4 and 5 in addition to FIGS. 1 to 3, the substrate SUB of FIG. 4 may not include the groove GRV illustrated in FIG. 3. The first electrode portion BE1 and the second electrode portions BE2 of the bottom electrode BE may be spaced apart from each other in an area in which the bottom electrode BE and the active layer ACT overlap. In one embodiment, the first electrode portion BE1 and the second electrode portions BE2 of the bottom electrode BE may have a same thickness and/or height.

In one embodiment, the first electrode portion BE1 and the second electrode portions BE2 of the bottom electrode BE may be connected to each other as illustrated in FIG. 5. For example, the bottom electrode BE may include an opening OP positioned between the first electrode portion BE1 and the second electrode portions BE2, and the first electrode portion BE1 and the second electrode portions BE2 of the bottom electrode BE may be connected to each other in areas in which the active layer ACT does not overlap the first electrode portion BE1 and the second electrode portions BE2 of the bottom electrode BE in the third direction D3

However, FIG. 5 only illustrates an embodiment related to the shape and/or structure of the bottom electrode BE applicable to the embodiment of FIG. 4, and the disclosure is not limited thereto. For example, in another embodiment, the first electrode portion BE1 and the second electrode portions BE2 of the bottom electrode BE may be separated from each other. In one embodiment, the first electrode portion BE1 of the bottom electrode BE may be connected to one electrode (e.g., the source electrode SE or the gate electrode GE) of the transistor T, and may have a shape and/or size corresponding to the electrode. In another embodiment, the first electrode portion BE1 of the bottom electrode BE may not be connected to the transistor T. In one embodiment, the second electrode portions BE2 of the bottom electrode BE may be spaced apart from the first electrode portion BE1, and may be connected to a wire (e.g., a power line supplying a constant voltage) positioned at the periphery or may be floating.

In embodiments, the first insulating layer INS1 and the active layer ACT disposed on the bottom electrode BE may have a valley VAL according to the shape and/or structure of the bottom electrode BE. For example, the first insulating layer INS1 and the active layer ACT may include a stepped portion and/or the valley VAL in a corresponding area between the first electrode portion BE1 and the second electrode portions BE2 of the bottom electrode BE.

In embodiments, the gate insulating layer GI may have a length greater than a length the gate electrode GE in the longitudinal direction of the channel region CH of the active layer ACT and may protrude over sides of the gate electrode GE. For example, the gate insulating layer GI may cover a part of each of the source region SR and the drain region DR that does not overlap the gate electrode GE around the channel region CH. Accordingly, the effective channel length of the transistor T may be appropriately extended and/or secured, and the operating characteristics of the transistor T may be improved and/or secured.

In one embodiment, the gate insulating layer GI may end on a stepped portion and/or the valley VAL of the first insulating layer INS1 and the active layer ACT. Accordingly, the end of the gate insulating layer GI may be positioned on the valley VAL of the first insulating layer INS1 and the active layer ACT.

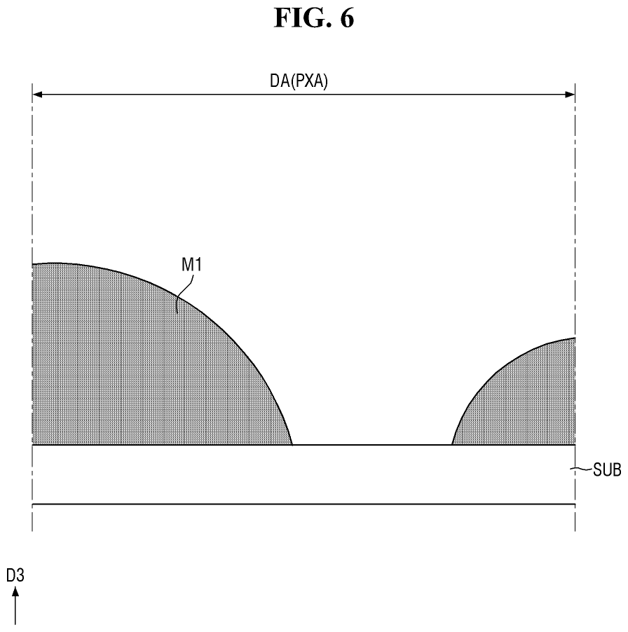

FIGS. 6 to 18 are schematic cross-sectional views showing a method for manufacturing the display device 100 according to an embodiment. For example, FIGS. 6 to 18 sequentially illustrate steps of forming the bottom electrode BE and the transistor T on the substrate SUB among the steps of manufacturing the display panel 110 of FIG. 3.

Referring to FIG. 6 in addition to FIGS. 1 to 3, the substrate SUB including at least the display area DA may be prepared. In one embodiment, the substrate SUB may be a glass substrate, but the disclosure is not limited thereto. The display area DA may include the pixel area PXA.

Thereafter, a first mask M1 (e.g., a photoresist pattern) may be disposed on the substrate SUB. The first mask M1 may expose an area in which the groove GRV of the substrate SUB is to be formed corresponding to the region of the bottom electrode BE illustrated in FIG. 3, and may be disposed on the substrate SUB to cover other areas of the substrate SUB. For example, the first mask M1 may be disposed on the substrate SUB to expose a partial area of the substrate SUB for forming the groove GRV in which the first electrode portion BE1 of the bottom electrode BE is to be positioned in the transistor area corresponding to the transistor T in FIG. 3, and to cover the remaining area of the substrate SUB.

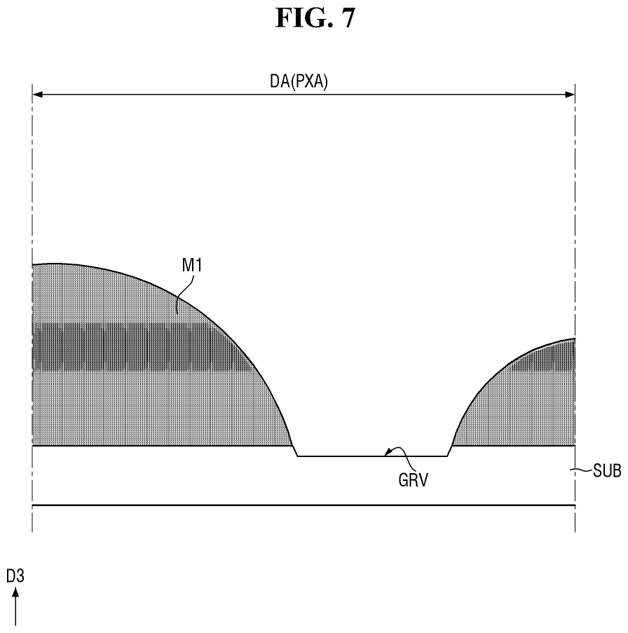

Referring to FIG. 7 in addition to FIGS. 1 to 6, the groove GRV may be formed in the substrate SUB by selectively etching the exposed area of the substrate SUB by using the first mask M1. For example, the groove GRV may be formed in the substrate SUB by etching a portion of the substrate SUB that is not covered by the first mask M1 to a thickness through a dry etching process or the like. Accordingly, the groove GRV may be formed in the substrate SUB corresponding to the area in which the first electrode portion BE1 of the bottom electrode BE is to be positioned. In one embodiment, the groove GRV may be formed to be longer than or equal to the width and/or length in which the first electrode portion BE1 of the bottom electrode BE is to be formed. After forming the groove GRV in the substrate SUB, the first mask M1 may be removed.

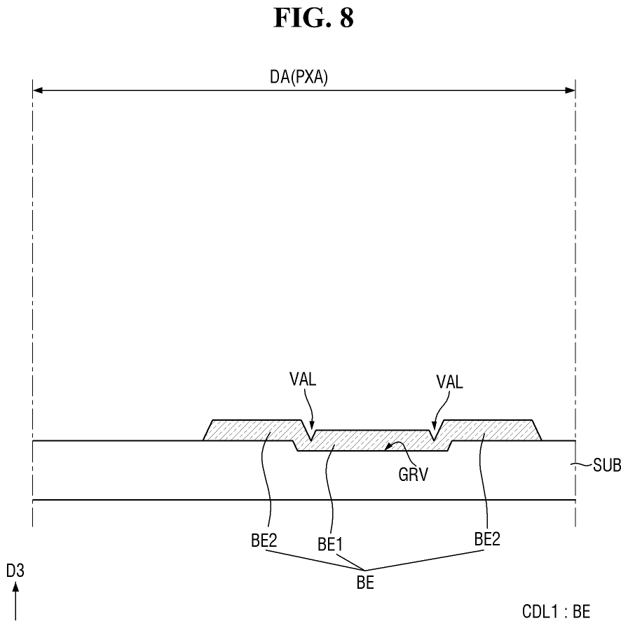

Referring to FIG. 8 in addition to FIGS. 1 to 7, the first conductive layer CDL1 including the bottom electrode BE may be formed on the substrate SUB. For example, a conductive layer may be formed by applying at least one conductive material as previously described on the substrate SUB including the groove GRV, and the bottom electrode BE may be formed by performing a patterning process (e.g., an etching process using a mask) of the conductive layer.

In one embodiment, the bottom electrode BE may be formed of a multilayer metal electrode. For example, a first metal layer including titanium (Ti), a second metal layer including aluminum (Al), and a third metal layer including titanium (Ti) may be sequentially formed on the substrate SUB including the groove GRV, and the bottom electrode BE having a triple-layer structure of titanium (Ti)/aluminum (Al)/titanium (Ti) may be formed by etching the first metal layer, the second metal layer, and the third metal layer. The material and/or structure of the bottom electrode BE may be changed depending on embodiments.

The bottom electrode BE may be formed on the groove GRV of the substrate SUB and the peripheral portion of the groove GRV. For example, the bottom electrode BE may include the first electrode portion BE1 disposed on the groove GRV of the substrate SUB, and the second electrode portions BE2 positioned on sides of the first electrode portion BE1 and disposed on the peripheral portion of the groove GRV of the substrate SUB.

In one embodiment, the bottom electrode BE may have a shape corresponding to the groove GRV of the substrate SUB. For example, the bottom electrode BE may have a stepped portion and/or the valley VAL corresponding to the groove GRV.

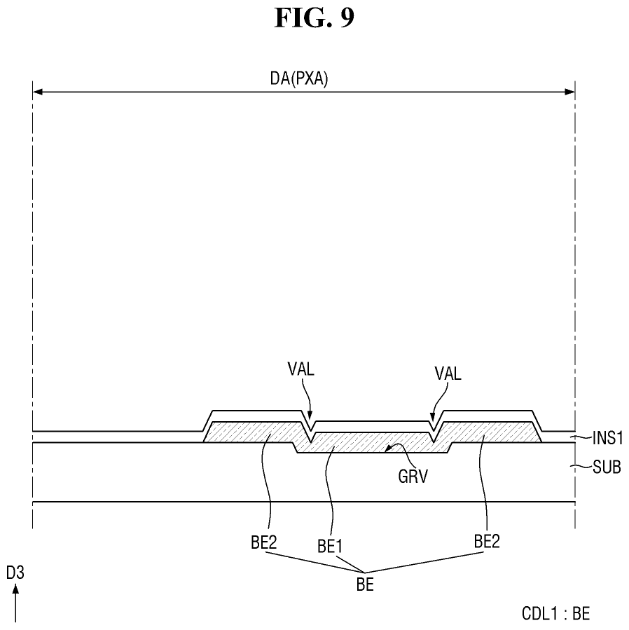

Referring to FIG. 9 in addition to FIGS. 1 to 8, the first insulating layer INS1 that covers the bottom electrode BE may be formed on the substrate SUB. In one embodiment, the first insulating layer INS1 may have a stepped portion and/or a cross-sectional shape corresponding to the stepped portion and/or the cross-sectional shape of the bottom electrode BE. For example, the first insulating layer INS1 may include the valley VAL in a corresponding area between the first electrode portion BE1 and the second electrode portions BE2 of the bottom electrode BE.

The first insulating layer INS1 may be formed by a film forming process of an insulating layer using at least one insulating material (for example, an inorganic insulating material) described above. In one embodiment, the first insulating layer INS1 may be formed of an inorganic insulating layer of two or more layers. For example, by sequentially forming a first inorganic insulating layer made of silicon nitride and a second inorganic insulating layer made of silicon oxide on the substrate SUB on which the bottom electrode BE is formed, the double-layer first insulating layer INS1 including the first inorganic insulating layer and the second inorganic insulating layer on the first inorganic insulating layer may be formed. The material and/or structure of the first insulating layer INS1 may be changed variously depending on the embodiments.

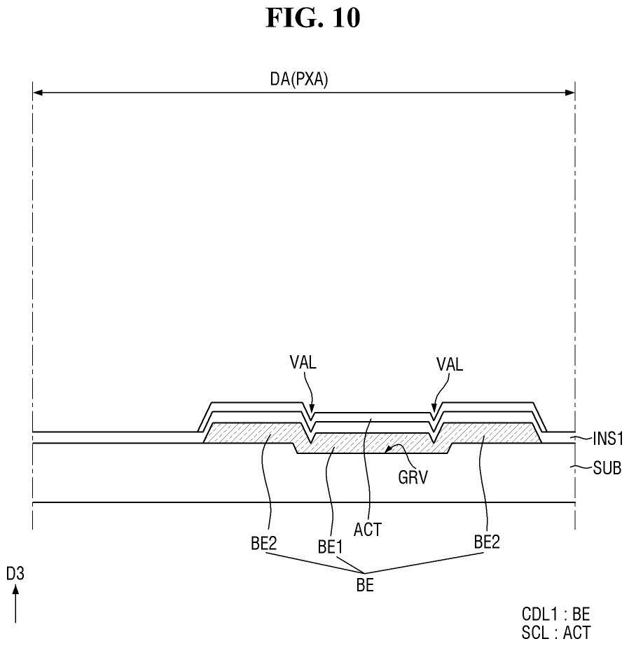

Referring to FIG. 10 in addition to FIGS. 1 to 9, the semiconductor layer SCL including the active layer ACT and the like may be formed on the first insulating layer INS1. For example, the active layer ACT may be formed in each transistor area on the substrate SUB.

The active layer ACT may be formed to overlap the bottom electrode BE in the third direction D3. For example, the active layer ACT may be formed to overlap the first electrode portion BE1 and the second electrode portions BE2 of the bottom electrode BE in the third direction D3. In one embodiment, the active layer ACT may have a stepped portion and/or a cross-sectional shape corresponding to the stepped portion and/or the cross-sectional shape of the first insulating layer INS1. For example, the active layer ACT may include the valley VAL in a corresponding area between the first electrode portion BE1 and the second electrode portions BE2 of the bottom electrode BE.

In one embodiment, the active layer ACT may be formed by a film forming process and patterning process (e.g., etching process using a mask) of a semiconductor layer by using at least one oxide semiconductor described above. For example, after forming a semiconductor layer made of indium-gallium-zinc oxide (IGZO) on the first insulating layer INS1, the active layer ACT may be formed by etching the semiconductor layer (e.g., wet etching). The material of the active layer ACT may be variously changed according to embodiments.

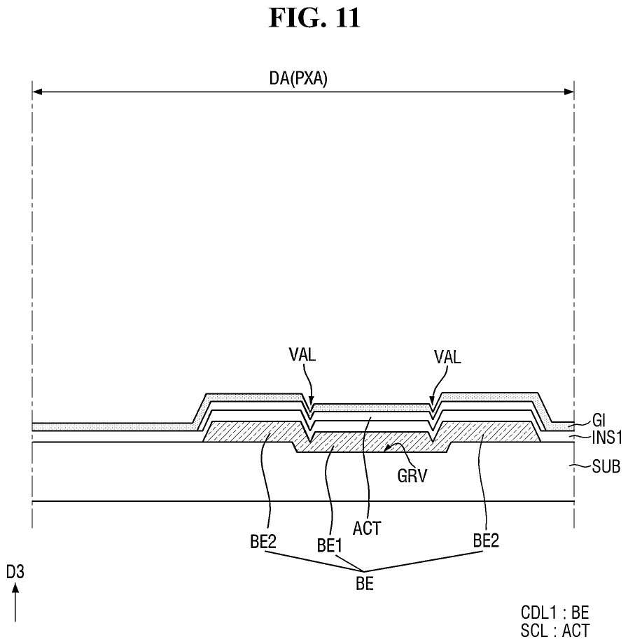

Referring to FIG. 11 in addition to FIGS. 1 to 10, the gate insulating layer GI covering the active layer ACT may be formed on the first insulating layer INS1. In one embodiment, the gate insulating layer GI may first be formed entirely on the substrate SUB including the display area DA and the like.

The gate insulating layer GI may be formed by a film forming process of an insulating layer using at least one insulating material (for example, an inorganic insulating material) described above. For example, the gate insulating layer GI including silicon oxide may be formed by depositing silicon oxide on the first insulating layer INS1 on which the active layer ACT and the like are formed. The material of the gate insulating layer GI may be variously changed according to embodiments.

In one embodiment, the gate insulating layer GI may have a stepped portion and/or cross-sectional shape corresponding to the stepped portion and/or cross-sectional shape of the first insulating layer INS1 and the active layer ACT. For example, the gate insulating layer GI may include the valley VAL in a corresponding area between the first electrode portion BE1 and the second electrode portions BE2 of the bottom electrode BE.

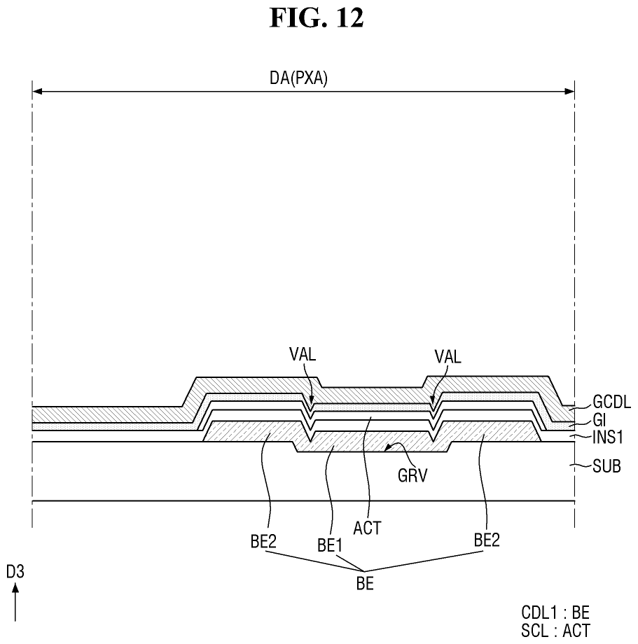

Referring to FIG. 12 in addition to FIGS. 1 to 11, a conductive layer GCDL covering the gate insulating layer GI may be formed on the substrate SUB. The conductive layer GCDL may be used to form the second conductive layer CDL2 including the gate electrode GE in FIG. 3, and may first be formed entirely over the display area DA or the like. For example, the conductive layer GCDL may be formed entirely on the gate insulating layer GI. The conductive layer GCDL may be formed by a film forming process of the conductive layer using at least one conductive material described above. In one embodiment, the conductive layer GCDL may have a stepped portion and/or cross-sectional shape corresponding to the stepped portion and/or cross-sectional shape of the gate insulating layer GI.

In one embodiment, the conductive layer GCDL may be formed of a multilayer metal layer. For example, a first metal layer including titanium (Ti), a second metal layer including aluminum (Al), and a third metal layer including titanium (Ti) may be sequentially formed on the gate insulating layer GI. Accordingly, in a subsequent process, the gate electrode GE formed from the conductive layer GCDL may be formed in a triple-layer structure of titanium (Ti)/aluminum (Al)/titanium (Ti). The material and/or structure of the conductive layer GCDL and the gate electrode GE formed from the conductive layer GCDL may be changed depending on the embodiments.

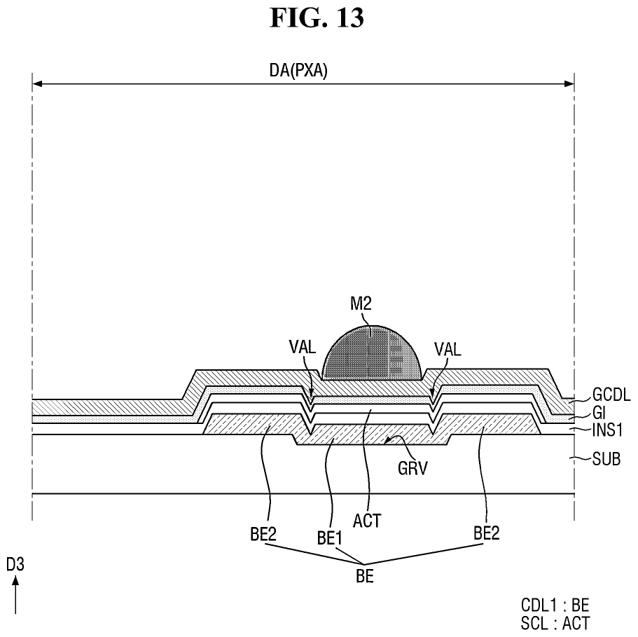

Referring to FIG. 13 in addition to FIGS. 1 to 12, a second mask M2 (e.g., a photoresist pattern) for patterning electrodes, wires, and/or patterns provided in the second conductive layer CDL2 may be disposed on the conductive layer GCDL. For example, in order to form the gate electrode GE on the first electrode portion BE1 of the bottom electrode BE, the second mask M2 overlapping the first electrode portion BE1 of the bottom electrode BE may be disposed on the conductive layer GCDL.

In one embodiment, after disposing the second mask M2, a heat treatment process may be performed at a temperature sufficient to slightly reflow the second mask M2, so that the second mask M2 may be made to have a more gentle curve. For example, by performing a first hard baking process on the second mask M2 at a temperature of approximately 130°° C., the side surface shape or the like of the second mask M2 may be slightly modified. Accordingly, in a subsequent process (e.g., an etching process of the conductive layer GCDL by using the second mask M2), the shapes (e.g., side surface inclinations) of the electrodes, wires, and/or patterns of the second conductive layer CDL2 patterned from the conductive layer GCDL may be appropriately controlled. For example, by heat-treating the second mask M2 such that the second mask M2 has a more gentle curve, the side surface inclination of the gate electrode GE may be controlled to be more gentle. Accordingly, disconnection of the upper layer and/or patterns formed on the gate electrode GE may be prevented.

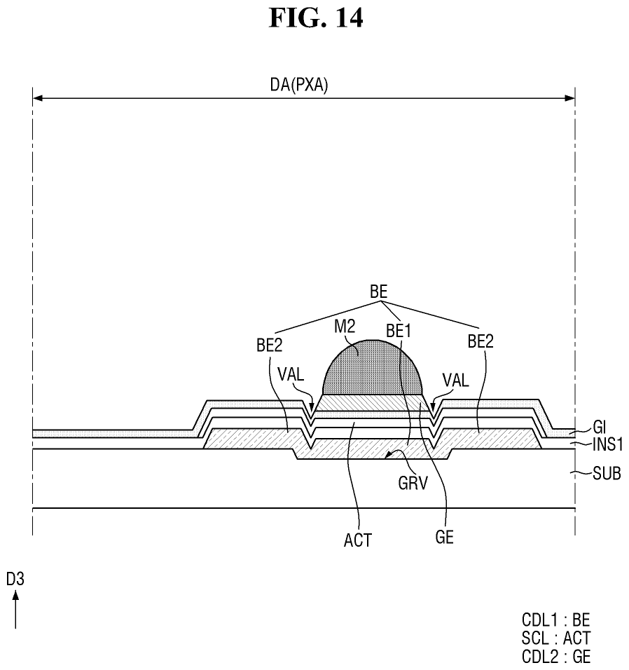

Referring to FIG. 14 in addition to FIGS. 1 to 13, by etching (e.g., dry etching) the conductive layer GCDL by using the second mask M2, the second conductive layer CDL2 including the gate electrode GE may be formed and/or patterned. For example, the gate electrode GE may be formed under the second mask M2 disposed on the first electrode portion BE1 of the bottom electrode BE.

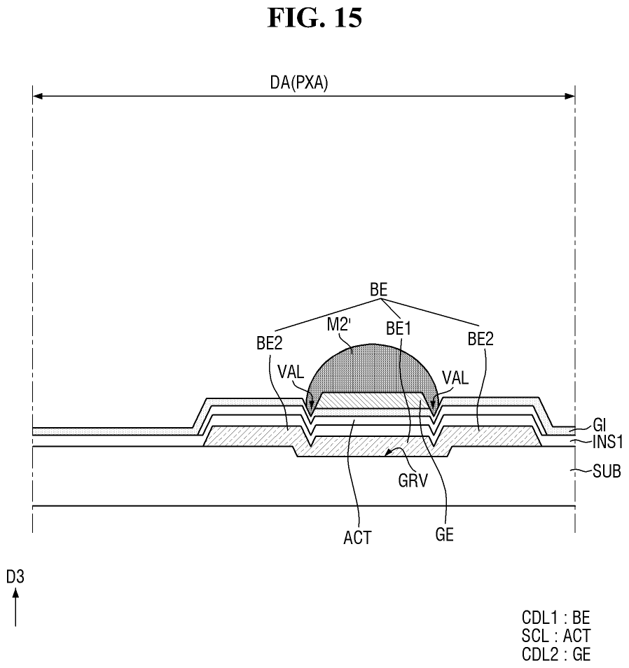

Referring to FIG. 15 in addition to FIGS. 1 to 14, the width of the second mask M2 may be extended by reflowing the second mask M2 through an additional heat treatment process for the second mask M2. For example, a second hard baking process may be performed on the second mask M2 at a sufficient temperature such that the second mask M2 may reflow and the width of the second mask M2 may be extended to be greater than or equal to the width of the gate electrode GE. For example, the width of the second mask M2 may be extended by performing the second hard baking process on the second mask M2 at a temperature in a range of approximately 135° C. to approximately 150° C. Accordingly, a second mask M2′ that covers the side surface of the gate electrode GE and has a more extended width may be formed on the gate electrode GE. The heat treatment temperature for the second mask M2 may be variously changed in consideration of material characteristics, process conditions or the like of the second mask M2, the substrate SUB, and/or elements disposed on the substrate SUB.

In one embodiment, reflow of the second mask M2 may be controlled by a stepped portion and/or the valley VAL formed in the gate insulating layer GI or the like. For example, a stepped portion and/or the valley VAL formed in the gate insulating layer GI may function as a dam that controls or limits the reflow range of the second mask M2. Accordingly, the end of the second mask M2′, which has a width extended by reflow, may be positioned on the valley VAL of the first insulating layer INS1, the active layer ACT, and/or the gate insulating layer GI formed on a stepped portion (e.g., the boundary area of the first electrode portion BE1 and the second electrode portions BE2) of the bottom electrode BE.

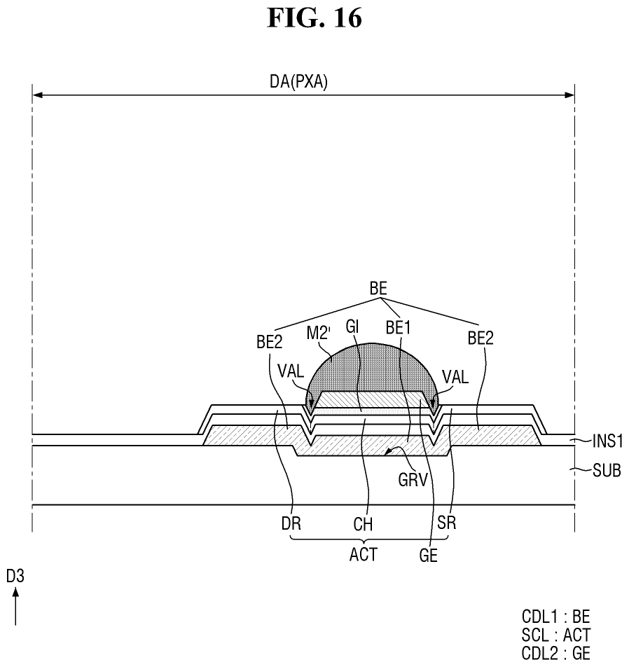

Referring to FIG. 16 in addition to FIGS. 1 to 15, by etching (e.g., dry etching) the gate insulating layer GI by using the second mask M2′ having a more extended width, the gate insulating layer GI, which covers a portion of the active layer ACT and exposes another portion of the active layer ACT while having a width and/or length greater than a width of the gate electrode GE, may be formed. For example, the gate insulating layer GI may be etched to cover a portion of the active layer ACT that overlaps the second mask M2′ and expose another portion of the active layer ACT in the third direction D3. Accordingly, the gate insulating layer GI that overlaps the gate electrode GE in the third direction D3 and has a width and/or length greater than that of the gate electrode GE may be formed under the second mask M2′. For example, the etched gate insulating layer GI may cover the channel region CH of the active layer ACT overlapping the gate electrode GE and a portion (e.g., a portion of the source region SR and the drain region DR) adjacent to the channel region CH, and may expose the remaining portion (e.g., the remaining portion of the source region SR and the drain region DR) of the active layer ACT.

By etching the gate insulating layer GI by using the second mask M2′ having a more extended width by a reflow method or the like, the gate insulating layer GI may be formed in an extended size as compared with the gate electrode GE without adding a process of forming a separate mask. Accordingly, the manufacturing process of the display device 100 may be simplified and manufacturing efficiency may be increased.

In one embodiment, by adjusting the position and/or size (e.g., width, length and/or depth) of the groove GRV formed in the substrate SUB, the shape of the gate insulating layer GI and/or the forming region and length of the gate insulating layer GI, or the like may be adjusted. The effective channel length of the transistor T may be appropriately adjusted by adjusting the forming region and length of the gate insulating layer GI.

After etching the gate insulating layer GI, the second mask M2′ may be removed. For example, the second mask M2′ may be removed through a strip or ashing process.

In the process of etching the gate insulating layer GI, the properties of the active layer ACT may be changed so that parts of the active layer ACT have different characteristics. Accordingly, the active layer ACT may be divided into multiple regions having different characteristics.

For example, mainly at a portion that is not covered by the etched gate insulating layer GI, an oxide bond may be broken to release oxygen, and oxygen vacancy may occur in the oxide semiconductor constituting the active layer ACT by an etching gas or the like. Accordingly, the active layer ACT may be divided into multiple regions (for example, the channel region CH, the source region SR, and the drain region DR) having different characteristics. In one embodiment, oxygen vacancy may occur mainly at a portion (for example, the source region SR and the drain region DR) of the active layer ACT that does not overlap the gate insulating layer GI in the third direction D3, and may diffuse to a portion of the region that overlaps the gate insulating layer GI and/or the gate electrode GE in the third direction D3.

In one embodiment, as the gate insulating layer GI has a width and/or length greater than a width and/or length of the gate electrode GE and is formed to extend to sides of the gate electrode GE, the length and/or area of the region in which the source region SR and the drain region DR are extended in the active layer ACT may be reduced, so that the effective channel length of the channel region CH may be appropriately extended and/or secured. For example, by forming the gate insulating layer GI having a more extended width and/or length under the gate electrode GE by using the second mask M2′ having an extended width, the range of the source region SR and the drain region DR in which oxygen vacancies are diffused in the etching process of the gate insulating layer GI, and/or the amount of hydrogen introduced into the source region SR and the drain region DR, or the like in a subsequent process (e.g., the formation process of the second insulating layer INS2) may be reduced. Accordingly, the threshold voltage roll-off (Vth roll-off) of the transistor T may be prevented, and the operating characteristics of the transistor T may be improved and/or stabilized.

By covering a portion of the active layer ACT to the extent that is greater or equal to the width and/or length of the gate electrode GE, the length of an effective channel formed in the channel region CH may be extended and/or secured although the size (e.g., the length of the channel region CH) of the transistor T in the high-resolution display device 100 is reduced. Accordingly, even in the high-resolution display device 100 including the smaller-sized transistors T, the operating characteristics of the transistors T may be appropriately and/or readily improved.

By covering a portion of the active layer ACT positioned adjacent to the gate electrode GE with the gate insulating layer GI having an extended width and/or length as compared with the gate electrode GE, short circuit defects that may occur between the gate electrode GE of the transistor T and the active layer ACT may be prevented. Accordingly, the reliability of the transistor T and the display device 100 including the same may be secured.

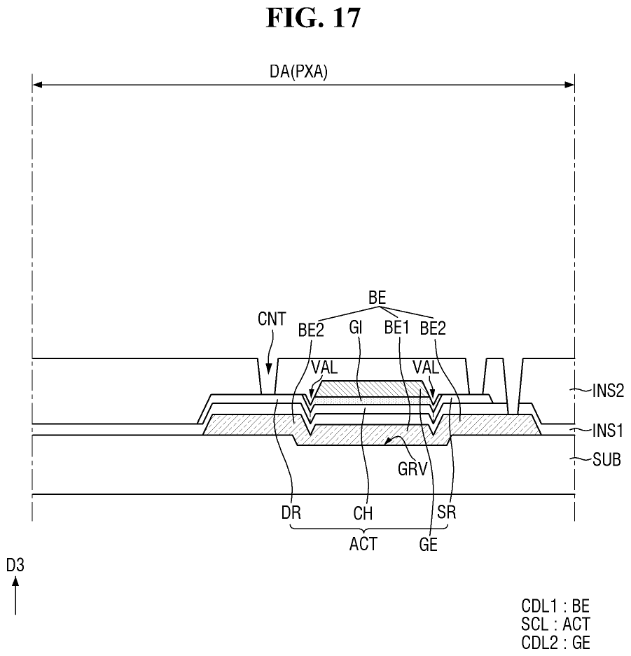

Referring to FIG. 17 in addition to FIGS. 1 to 16, the second insulating layer INS2 may be formed on the first insulating layer INS1. The second insulating layer INS2 may be formed entirely on the display area DA to cover the active layer ACT, the gate insulating layer GI, and the gate electrode GE. The second insulating layer INS2 may be formed by a film forming process of an insulating layer using at least one insulating material (for example, an inorganic insulating material) described above.

In one embodiment, the second insulating layer INS2 may be formed of an inorganic insulating layer of two or more layers. For example, by sequentially forming a first inorganic insulating layer made of silicon oxide and a second inorganic insulating layer made of silicon nitride on the first insulating layer INS1 on which the active layer ACT, the gate insulating layer GI, and the gate electrode GE are formed, a double-layered second insulating layer INS2 may be formed. The material and/or structure of the second insulating layer INS2 may be changed variously depending on the embodiments.

During the process of forming the second insulating layer INS2, hydrogen may be introduced into the active layer ACT. As hydrogen is introduced into the active layer ACT, a portion of the active layer ACT may become conductive (e.g., N-type conductive), mainly at a portion containing a large number of oxygen vacancies. For example, the source region SR and drain region DR may be formed conductive.

In one embodiment, a portion of each of the source region SR and the drain region DR adjacent to the channel region CH may be covered by the gate insulating layer GI, and thus the amount of hydrogen introduced into the source region SR and the drain region DR and/or the formation range of the source region SR and drain region DR may be controlled or reduced. Accordingly, the length of the channel region CH and/or an effective channel formed in the channel region CH may be extended and/or secured.

In one embodiment, after the second insulating layer INS2 is formed, contact holes CNT exposing a part of each of the active layers ACT may be formed in the second insulating layer INS2. For example, the contact holes CNT exposing a part of each of the source region SR and the drain region DR may be formed by an etching (e.g., dry etching) process of the second insulating layer INS2 by using a mask. In one embodiment, in case that the bottom electrode BE is connected to the source electrode SE, the contact hole CNT exposing a part of the bottom electrode BE may be formed in the second insulating layer INS2 and the first insulating layer INS1. In FIG. 17, only one contact hole CNT among the contact holes CNT formed in the second insulating layer INS2 and/or the first insulating layer INS1 is indicated by a reference sign.

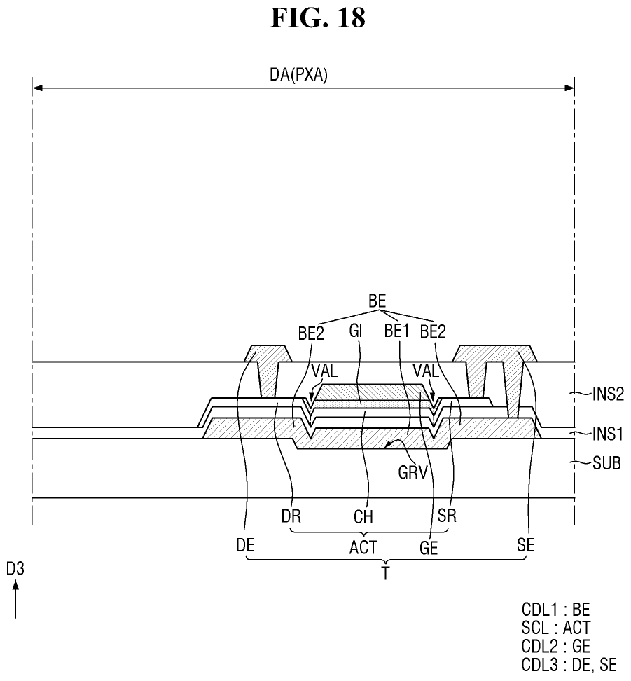

Referring to FIG. 18 in addition to FIGS. 1 to 17, the third conductive layer CDL3 including the source electrode SE and the drain electrode DE may be formed on the second insulating layer INS2. For example, a conductive layer may be formed by applying at least one conductive material as previously described on the second insulating layer INS2 in which the contact holes CNT are formed, and a patterning process (e.g., etching process using a mask) of the conductive layer may be performed to form the source electrode SE and the drain electrode DE.

The source electrode SE may be formed to be connected to the source region SR of the active layer ACT, and the drain electrode DE may be formed to be connected to the drain region DR of the active layer ACT. In one embodiment, the source electrode SE may be formed to be connected to the bottom electrode BE. In one embodiment, in case that at least one of the source region SR or the drain region DR replaces at least one of the source electrode SE or the drain electrode DE, at least one of the source electrode SE or the drain electrode DE may not be formed.

Through the above-described process, multiple pixel transistors including the transistor T may be formed in the display area DA. In one embodiment, driver transistors may be formed in the driving circuit area in substantially the same or similar manner as the above-described embodiment. For example, pixel transistors and driver transistors may be formed simultaneously on the display panel 110. In one embodiment, elements provided on the same conductive layer or the same semiconductor layer in the display panel 110 may be formed simultaneously.

After forming the transistor T, a process of forming the third insulating layer INS3 illustrated in FIG. 3 may be performed. The third insulating layer INS3 may cover circuit elements, wires, and/or conductive patterns of the panel circuit layer PCL including the transistor T. Accordingly, the panel circuit layer PCL of the display panel 110 may be formed.

In one embodiment, in case that the display panel 110 includes the light emitting element layer LEL and the encapsulation layer ENL disposed on the panel circuit layer PCL, the light emitting element layer LEL and the encapsulation layer ENL may be sequentially formed on the panel circuit layer PCL. Through the above-described processes, the display panel 110 and the display device 100 including the same according to the embodiment of FIG. 3 may be manufactured.

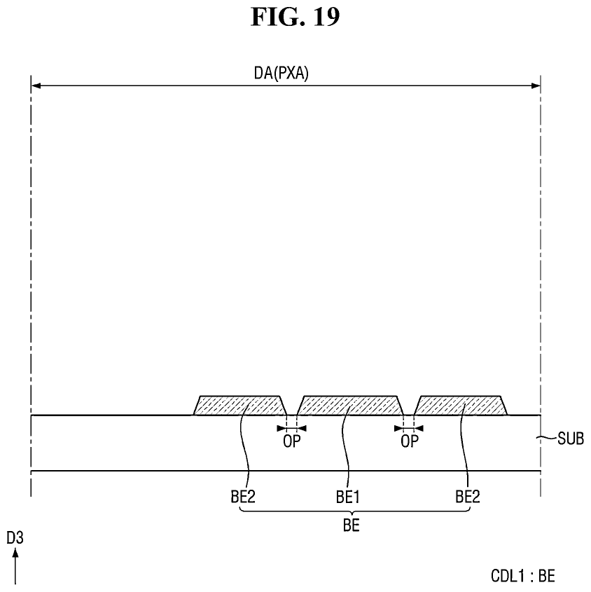

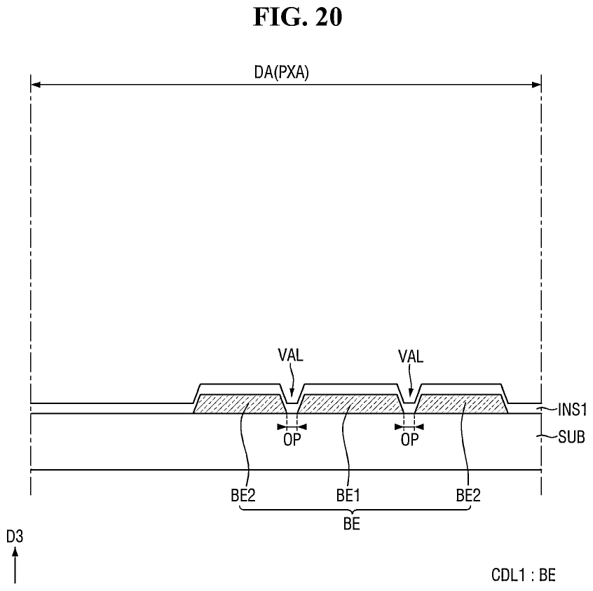

FIGS. 19 and 20 are schematic cross-sectional views illustrating a method for manufacturing the display device 100 according to an embodiment. For example, FIGS. 19 and 20 sequentially illustrate the steps of forming the bottom electrode BE and the first insulating layer INS1 on the substrate SUB among the steps of manufacturing the display panel 110 of FIG. 4. The formation steps of the active layer ACT, the gate insulating layer GI, the gate electrode GE, the second insulating layer INS2, the source electrode SE, the drain electrode DE, and the like, which are performed after the formation of the first insulating layer INS1, may be performed in substantially the same or similar manner as the previously described embodiment.

Referring to FIGS. 19 and 20 in addition to FIGS. 1 to 18, the bottom electrode BE and the first insulating layer INS1 may be sequentially formed on the substrate SUB. The bottom electrode BE may be formed to include the opening OP between the first electrode portion BE1 and the second electrode portions BE2. For example, the first electrode portion BE1 and the second electrode portions BE2 of the bottom electrode BE may be formed to be connected to each other first and disconnected from each other in the area in which the bottom electrode BE and the active layer ACT overlap in the third direction D3. In another embodiment, the first electrode portion BE1 and the second electrode portions BE2 of the bottom electrode BE may be formed separately from each other. Accordingly, the first insulating layer INS1 formed on the substrate SUB to cover the bottom electrode BE after the formation of the bottom electrode BE may have a stepped portion and/or the valley VAL according to the shape and/or structure of the bottom electrode BE. As illustrated in FIG. 4, the active layer ACT and the gate insulating layer GI formed on the first insulating layer INS1 may have a stepped portion and/or the valley VAL according to the shape and/or structure of the bottom electrode BE and the first insulating layer INS1.

Accordingly, a stepped portion and/or the valley VAL for controlling the reflow of a mask (e.g., the second masks M2 and M2′ in FIGS. 13 to 16) used for patterning the gate electrode GE and the gate insulating layer GI in a subsequent process without forming the groove GRV in the substrate SUB, may be formed in the first insulating layer INS1, the active layer ACT, and/or the gate insulating layer GI. For example, the display panel 110 according to the embodiment of FIG. 4 may be manufactured using fewer masks as compared with the display panel 110 according to the embodiment of FIG. 3. For example, in manufacturing the display panel 110 according to the embodiment of FIG. 4, the process of forming the first mask M1 illustrated in FIGS. 6 and 7 and the etching process of the substrate SUB by using the first mask M1 may be omitted. In one embodiment, the area in which the gate insulating layer GI is formed may be adjusted by adjusting the position and size of the first electrode portion BE1 and the second electrode portions BE2 of the bottom electrode BE, and/or the distance (or the size of the opening OP) therebetween.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a bottom electrode disposed on a substrate, and comprising a first electrode portion and second electrode portions positioned on sides of the first electrode portion;
a first insulating layer disposed on the substrate, and covering the bottom electrode;
an active layer disposed on the first insulating layer, and comprising a channel region disposed on the first electrode portion of the bottom electrode and a source region and a drain region disposed on the second electrode portions of the bottom electrode;
a gate insulating layer disposed on a portion of the active layer comprising the channel region, and exposing the source region and the drain region; and
a gate electrode disposed on the gate insulating layer, and overlapping the channel region of the active layer in a thickness direction of the substrate, wherein
the first insulating layer and the active layer comprise a valley in a corresponding area between the first electrode portion and the second electrode portions of the bottom electrode, and
the gate insulating layer comprises an end positioned on the valley of the active layer, and has a length greater than a length of the gate electrode in a longitudinal direction of the channel region.

2. The display device of claim 1, wherein the gate insulating layer protrudes over sides of the gate electrode in the longitudinal direction of the channel region, and covers a part of each of the source region and the drain region adjacent to the channel region.

3. The display device of claim 1, wherein the substrate comprises a groove overlapping the channel region and the gate electrode in the thickness direction.

4. The display device of claim 3, wherein the first electrode portion of the bottom electrode is disposed on the groove of the substrate.

5. The display device of claim 4, wherein the second electrode portions of the bottom electrode extend from the first electrode portion, are disposed on a peripheral portion of the groove of the substrate, and have a height greater than a height of the first electrode portion.

6. The display device of claim 5, wherein the bottom electrode comprises a valley positioned at a boundary between the first electrode portion and the second electrode portions and corresponding to the groove of the substrate.

7. The display device of claim 1, wherein the first electrode portion and the second electrode portions of the bottom electrode are spaced apart from each other in an area in which the channel region and the source and the drain regions are connected.

8. The display device of claim 1, wherein the bottom electrode comprises an opening positioned between the first electrode portion and the second electrode portions.

9. The display device of claim 1, further comprising:
a second insulating layer disposed on the first insulating layer, and covering the active layer, the gate insulating layer, and the gate electrode.

10. The display device of claim 9, wherein the first transistor comprises at least one of:
a source electrode disposed on the second insulating layer, and connected to the source region of the active layer; and
a drain electrode disposed on the second insulating layer, and connected to the drain region of the active layer.

11. The display device of claim 10, further comprising:
a third insulating layer disposed on the second insulating layer, and covering at least one of the source electrode and the drain electrode;
a light emitting element layer comprising a light emitting element disposed on the third insulating layer; and
an encapsulation layer covering the light emitting element layer.

12. A method for manufacturing a display device, comprising:
forming, on a substrate, a bottom electrode comprising a first electrode portion and second electrode portions positioned on sides of the first electrode portion;
forming, on the substrate, a first insulating layer covering the bottom electrode and comprising a valley in a corresponding area between the first electrode portion and the second electrode portions of the bottom electrode;
forming, on the first insulating layer, an active layer on the first electrode portion and the second electrode portions of the bottom electrode;
sequentially forming a gate insulating layer covering the active layer and a conductive layer covering the gate insulating layer, on the first insulating layer;
disposing a mask overlapping the first electrode portion of the bottom electrode in a thickness direction of the substrate, on the conductive layer;
forming a gate electrode under the mask by etching the conductive layer;
extending a width of the mask such that the mask covers a side surface of the gate electrode; and
etching the gate insulating layer to cover a portion of the active layer that overlaps the mask and expose another portion of the active layer.

13. The method of claim 12, wherein the extending of the width of the mask comprises reflowing the mask through a heat treatment process.

14. The method of claim 13, wherein after the reflowing of the mask, an end of the mask is positioned on the valley of the first insulating layer.

15. The method of claim 12, wherein after the etching of the gate insulating layer, the gate insulating layer covers a channel region of the active layer and a portion adjacent to the channel region and exposes a remaining portion of the active layer.

16. The method of claim 12, further comprising:
before the forming of the bottom electrode, forming a groove in the substrate by etching the substrate to correspond to an area in which the first electrode portion of the bottom electrode is to be positioned.

17. The method of claim 16, wherein the bottom electrode is formed on the groove of the substrate and a peripheral portion of the groove.

18. The method of claim 12, wherein the bottom electrode is formed to comprise an opening between the first electrode portion and the second electrode portions.

19. The method of claim 12, further comprising:
after the etching of the gate insulating layer, forming a second insulating layer covering the active layer, the gate insulating layer, and the gate electrode on the first insulating layer.

20. The method of claim 19, further comprising:
forming at least one of a source electrode connected to the source region of the active layer and a drain electrode connected to a drain region of the active layer, on the second insulating layer.
